(19) United States
(12) Patent Application Publication
(10) Pub. No.: US 2025/0285802 A1
(43) Pub. Date: Sep. 11, 2025

(54) TRANSFORMER MODULE

(71) Applicant: KABUSHIKI KAISHA TOYOTA JIDOSHOKKI, Kariya-shi (JP)

(72) Inventors: Yoshifumi TADA, Kariya-shi (JP); Katsuya USAMI, Kariya-shi (JP); Atsushi OSHIMA, Kariya-shi (JP)

(73) Assignee: KABUSHIKI KAISHA TOYOTA JIDOSHOKKI, Kariya-shi (JP)

(21) Appl. No.: 19/063,478

(22) Filed: Feb. 26, 2025

(30) Foreign Application Priority Data
Mar. 7, 2024 (JP) 2024-035230

(51) Int. Cl. H01F 27/29; H05K 1/18

(52) U.S. Cl. CPC H01F 27/292; H05K 1/181

(57) ABSTRACT

A transformer module includes multiple lead terminals, each of which includes a bent portion bent along a substrate and a joint portion extending along the substrate. Lands that are arranged in parallel on the substrate include an enlarged land and standard lands. Joint portions of the lead terminals, which are adjacent to each other in a parallel arrangement direction of the lead terminals and have the same electric potential, are soldered to the enlarged land via a solder layer. Each joint portion is soldered to one of the standard lands via the corresponding solder layer. The enlarged land is formed by connecting, via a connection land and in the parallel arrangement direction, the standard lands to which the lead terminals, adjacent to each other in the parallel arrangement direction and having the same electric potential, are intended to be soldered.

### CROSS-REFERENCE TO RELATED APPLICATIONS

This application is based upon and claims the benefit of priority from Japanese Patent Application No. 2024-035230, filed on Mar. 7, 2024, the entire contents of which are incorporated herein by reference.

### BACKGROUND

### 1. Field

The present disclosure relates to a transformer module.

### 2. Description of Related Art

The transformer module includes a substrate and a transformer. The transformer comprises a winding and multiple lead terminals electrically connected to the winding. The lead terminals are arranged in parallel. Each of the lead terminals is bent from its root, and a portion including its tip is soldered to a land of the substrate via a solder layer.

In a transformer module, the transformer is a relatively large component. Consequently, when the transformer module is subjected to external vibrations or similar forces, the transformer is prone to vibration as well. The bent portions of the lead terminals are locations where stress is likely to occur when the transformer vibrates. Therefore, it is preferable to reinforce the bent portions of the lead terminals in the transformer module. One method of reinforcement involves joining a portion of the solder layer to the bent portion. In order to join a portion of the solder layer to the bent portion, it is necessary to increase the amount of solder paste applied to the land. As a method of increasing the amount of solder paste applied to the land, for example, the technique disclosed in Japanese Laid-Open Patent Publication No. H7-131139 is known. In this publication, a wiring board includes a land for soldering terminals and an auxiliary land provided continuously with the land. Since the solder paste applied to the auxiliary land moves toward the land, the amount of the solder paste supplied to the land is increased.

However, as disclosed in the above publication, adding an auxiliary land to the substrate results in an increase in the overall size of the substrate.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a transformer module includes a transformer and a substrate. The transformer includes multiple lead terminals electrically connected to corresponding windings, and a terminal mount on which the multiple lead terminals are arranged in parallel. Multiple lands to which the lead terminals are respectively soldered are arranged in parallel on the substrate. Each of the lead terminals includes a bent portion bent along the substrate and a joint portion extending along the substrate. Each joint portion is soldered to the corresponding land via a solder layer. The lands include an enlarged land and multiple standard lands. The joint portions of ones of the lead terminals are soldered to the enlarged land via the corresponding solder layer. The ones of the lead terminals are adjacent to each other in a parallel arrangement direction in which the lead terminals are arranged in parallel. The ones of the lead terminals have a same electric potential. Each joint portion is soldered to one of the standard lands via the corresponding solder layer. The enlarged land is formed by connecting, via a connection land and in the parallel arrangement direction, the standard lands to which the lead terminals, adjacent to each other in the parallel arrangement direction and having the same electric potential, are intended to be soldered.

Other features and aspects will be apparent from the following detailed description, the drawings, and the claims.

### BRIEF DESCRIPTION OF THE DRAWINGS

FIG. 1 is a plan view showing a transformer module according to an embodiment.

FIG. 2 is a side view of the transformer module shown in FIG. 1.

FIG. 3 is an enlarged view showing a lead terminal and a solder layer in the enlarged land shown in FIG. 1.

FIG. 4 is a plan view showing the lead terminals and the solder layer in the enlarged land shown in FIG. 3.

FIG. 5 is a plan view showing a substrate of a reference example.

FIG. 6 is a plan view showing a transformer module according to a first modification.

FIG. 7 is a plan view showing a transformer module according to a second modification.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

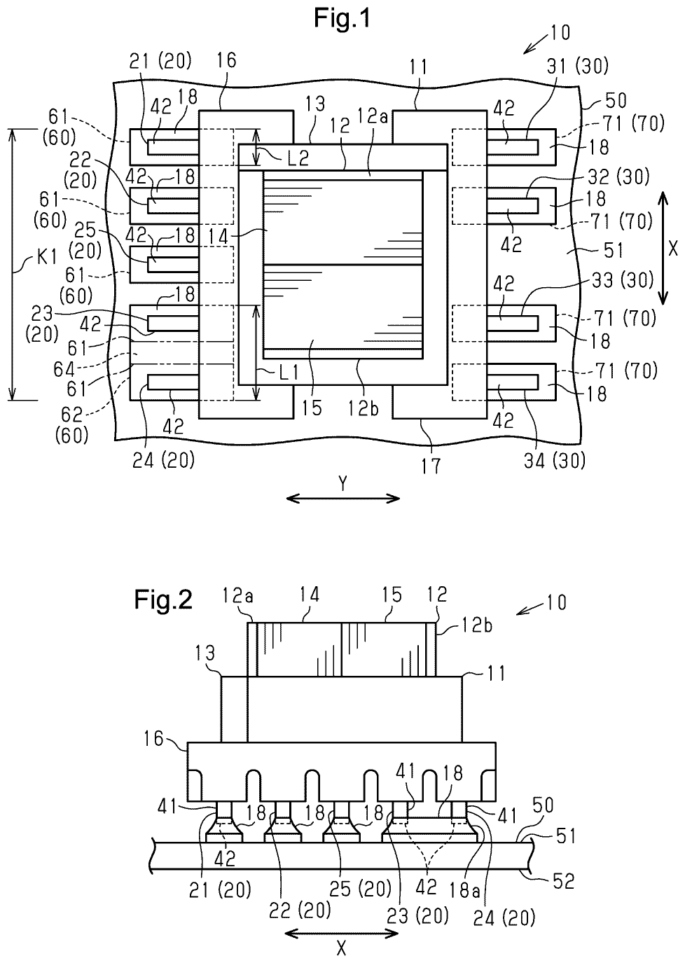

A transformer module 10 according to an embodiment will now be described with reference to FIGS. 1 to 5.

### Transformer Module

As shown in FIGS. 1 and 2, the transformer module 10 includes a transformer 11 and a substrate 50, to which the transformer 11 is soldered.

The transformer 11 includes a bobbin 12, a magnetic core 13 combined with an outer peripheral portion of the bobbin 12, and a primary winding 14 and a secondary winding 15 wound around the bobbin 12. The bobbin 12 includes a flange portion 12a at one end in the axial direction and a flange portion 12b at the other end in the axial direction. The primary winding 14 and the secondary winding 15 are wound around the bobbin 12 such that the one flange portion 12a, the primary winding 14, the secondary winding 15, and the other flange portion 12b are arranged in that order in the axial direction. The number of turns is different between the primary winding 14 and the secondary winding 15. The magnetic core 13 may be an EI-type core or an EE-type core. A primary-side terminal mount 16 and a secondary-side terminal mount 17 are formed below the bobbin 12. Each of the primary-side terminal mount 16 and the secondary-side terminal mount 17 has the shape of a block, and their longitudinal directions agree with each other.

The primary-side terminal mount 16 is provided with five primary-side lead terminals 20. The five primary-side lead terminals 20 include a first lead terminal 21, a second lead terminal 22, a dummy lead terminal 25, a third lead terminal 23, and a fourth lead terminal 24, which are arranged in that order from one end to the other end in the longitudinal direction of the primary-side terminal mount 16. The first lead terminal 21 to the fourth lead terminal 24 and the dummy lead terminal 25 are arranged in parallel on the primary-side terminal mount 16 at equal intervals in the longitudinal direction of the primary-side terminal mount 16. Therefore, the direction in which the five primary-side lead terminals 20 are arranged in parallel agrees with the longitudinal direction of the primary-side terminal mount 16.

Any two of the primary-side lead terminals 20 that are adjacent to each other in the longitudinal direction of the primary-side terminal mount 16 are separated from each other by a distance greater than or equal to the insulation distance. The first lead terminal 21 to the fourth lead terminal 24 are electrically connected to the primary winding 14. The first lead terminal 21 and the second lead terminal 22, which are adjacent to each other in the longitudinal direction of the primary-side terminal mount 16, have the same electric potential, and the third lead terminal 23 and the fourth lead terminal 24, which are adjacent to each other in the longitudinal direction of the primary-side terminal mount 16, have the same electric potential.

Accordingly, the transformer 11 included in the transformer module 10 includes the first lead terminal 21 to the fourth lead terminal 24, which are electrically connected to the primary winding 14, and the first lead terminal 21 to the fourth lead terminal 24 are arranged in parallel on the primary-side terminal mount 16.

The secondary-side terminal mount 17 is provided with four secondary-side lead terminals 30. The four secondary-side lead terminals 30 include a first lead terminal 31, a second lead terminal 32, a third lead terminal 33, and a fourth lead terminal 34, which are arranged in that order from one end to the other end in the longitudinal direction of the secondary-side terminal mount 17. The first lead terminal 31 to the fourth lead terminal 34 are arranged in parallel in the longitudinal direction of the secondary-side terminal mount 17. The parallel arrangement direction of the four secondary-side lead terminals 30 agrees with the longitudinal direction of the secondary-side terminal mount 17 and also agrees with the parallel arrangement direction of the five primary-side lead terminals 20.

The first lead terminal 31 to the fourth lead terminal 34 are electrically connected to the secondary winding 15. The first lead terminal 31 and the second lead terminal 32, which are adjacent to each other in the longitudinal direction of the secondary-side terminal mount 17, have different electric potentials, and the third lead terminal 33 and the fourth lead terminal 34, which are adjacent to each other in the longitudinal direction of the secondary-side terminal mount 17, have different electric potentials. The second lead terminal 32 and the third lead terminal 33, which are adjacent to each other in the longitudinal direction of the secondary-side terminal mount 17, have different electric potentials.

Accordingly, the transformer 11 included in the transformer module 10 includes the first lead terminal 31 to the fourth lead terminal 34, which are electrically connected to the secondary winding 15, and the first lead terminal 31 to the fourth lead terminal 34 are arranged in parallel on the secondary-side terminal mount 17.

In the transformer 11, for example, when AC input power is input to the primary winding 14 through the first lead terminal 21 and the fourth lead terminal 24 on the primary side, an output voltage is generated at the first lead terminal 31 and the third lead terminal 33 on the secondary side. In the transformer 11, when AC input power is input to the primary winding 14 through the second lead terminal 22 and the third lead terminal 23 on the primary side, an output voltage is generated at the second lead terminal 32 and the fourth lead terminal 34 on the secondary side. An input voltage is converted into an output voltage in accordance with the ratio of the number of turns between the primary winding 14 and the secondary winding 15.

Each of the primary-side lead terminals 20 and the secondary-side lead terminals 30 is formed by bending a thin plate into an L-shape. The primary-side lead terminals 20 and the secondary-side lead terminals 30 have the same shape. Therefore, in the following description, the same component names and reference numerals are assigned to the components included in both the primary-side lead terminals 20 and the secondary-side lead terminals 30.

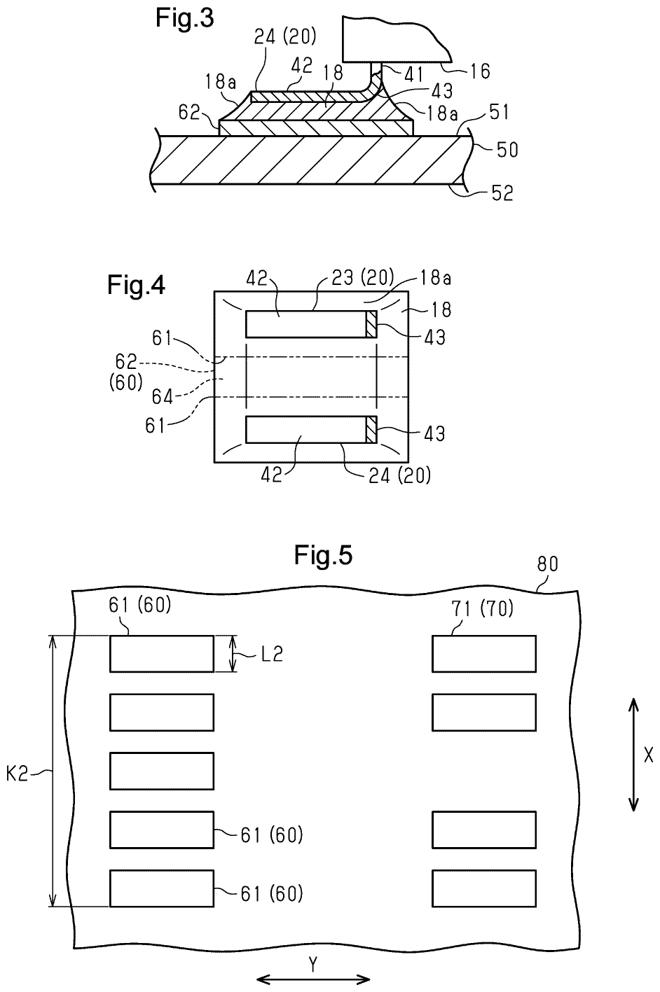

As shown in FIGS. 3 and 4, each of the primary-side lead terminals 20 and the secondary-side lead terminals 30 integrally includes a rectangular plate-shaped extending portion 41, a rectangular plate-shaped joint portion 42, and a bent portion 43. The extending portion 41 extends from the primary-side terminal mount 16 or the secondary-side terminal mount 17 on which the terminal 20, 30 is disposed. The joint portion 42 extends so as to intersect with the extending portion 41. The bent portion 43, connects the extending portion 41 and the joint portion 42 to each other.

### Substrate

As shown in FIGS. 1 and 2, the substrate 50 includes a first main surface 51 and a second main surface 52, which are located on opposite sides in the thickness direction. The substrate 50 includes lands provided on the first main surface 51. The lands include multiple primary-side lands 60 and multiple secondary-side lands 70. In plan view in which the transformer module 10 is viewed in the thickness direction, the primary-side lands 60 are disposed at positions corresponding to the primary-side terminal mount 16 of the transformer 11, and the secondary-side lands 70 are disposed at positions corresponding to the secondary-side terminal mount 17 of the transformer 11. In plan view in which the transformer module 10 is viewed in the thickness direction, the primary-side lands 60 and the secondary-side lands 70 are disposed with the transformer 11 interposed therebetween.

The primary-side lead terminals 20 are soldered to the primary-side lands 60 via solder layers 18. Accordingly, the primary-side lands 60, to which the primary-side lead terminals 20 are respectively soldered, are arranged in parallel on the substrate 50. The secondary-side lead terminals 30 are soldered to the secondary-side lands 70 via the corresponding solder layers 18. Accordingly, the secondary-side lands 70, to which the secondary-side lead terminals 30 are respectively soldered, are arranged in parallel on the substrate 50.

Each of the primary-side lands 60 has a rectangular shape. The primary-side lands 60 are arranged such that the short sides of all the primary-side lands 60 extend in the same direction. The direction in which the short sides of the primary-side lands 60 extend is defined as a first direction X of the substrate 50. The direction in which the long sides of the primary-side lands 60 extends is defined as a second direction Y of the substrate 50. The primary-side lands 60 are arranged in parallel in the first direction X of the substrate 50. Accordingly, the parallel arrangement direction of the primary-side lands 60 agrees with the first direction X of the substrate 50. Any two of the primary-side lands 60 that are adjacent to each other in the first direction X of the substrate 50 are separated from each other in the first direction X by a distance greater than or equal to the insulation distance.

The primary-side lands 60 include standard lands 61 to each of which one joint portion 42 is soldered via the solder layer 18. The primary-side lands 60 include an enlarged land 62 to which two joint portions 42 are soldered. On the substrate 50, three standard lands 61 and one enlarged land 62 are arranged in parallel from one end to the other end in the first direction X of the substrate 50.

Each standard land 61 has a surface area sufficient to allow the application of an amount of solder paste necessary for soldering a single joint portion 42 to the primary-side land 60 via a solder layer 18. This amount of solder paste is sufficient to form the solder layer 18 so that it joins to the entire back surface and side surfaces of the joint portion 42 while securing the joint portion 42 to the primary-side land 60.

The standard lands 61 and the enlarged land 62 have the same dimension in the second direction Y. The standard lands 61 and the enlarged land 62 have different dimensions in the first direction X. A dimension L1 of the enlarged land 62 in the first direction X is greater than a dimension L2 of the standard land 61 in the first direction X. The dimension L1 of the enlarged land 62 is sufficiently greater than twice the dimension L2 of the standard land 61.

A substrate 80 of a reference example shown in FIG. 5 will now be described.

The substrate 80 of the reference example includes five standard lands 61 as the primary-side lands 60 and four standard lands 71 as the secondary-side lands 70. The dimensions in the first direction X of the standard lands 61, 71 in the reference example are the same as the dimension L2 of the standard lands 61, 71 in the embodiment. The dimensions in the second direction Y of the standard lands 61, 71 in the reference example are the same as the dimension in the second direction Y of the standard lands 61, 71 in the embodiment. The distance between any two of the standard lands 61, 71 adjacent to each other in the first direction X is also the same as the distance between any two of the standard lands 61, 71 adjacent to each other in the first direction X in the embodiment. On the substrate 80 of the reference example, two standard lands 61 are provided in place of the enlarged land 62.

As shown in FIGS. 1 and 4, the enlarged land 62 of the embodiment is formed by connecting two standard lands 61 that are located at one end in the first direction X and adjacent to each other in the first direction X on the substrate 80 of the reference example. Specifically, as indicated by the long-dash double-short-dash lines in FIG. 1, the enlarged land 62 is formed by connecting, with a connection land 64 and in the parallel arrangement direction, two standard lands 61 to which the third lead terminal 23 and the fourth lead terminal 24, having the same potential and being adjacent to each other in the parallel arrangement direction, are respectively intended to be soldered. These two standard lands 61 are connected to each other over the entire length of the standard lands 61 via the connection land 64. That is, the connection land 64 connects the standard lands 61 adjacent to each other in the parallel arrangement direction over the entire standard lands 61 in the direction orthogonal to the parallel arrangement direction Accordingly, the dimension of the enlarged land 62 in the second direction Y of the substrate 50 is the same as the dimension of the standard land 61 in the second direction Y, while the dimension of the enlarged land 62 in the first direction X of the substrate 50 is sufficiently greater than twice the dimension of the standard land 61 in the first direction X. The surface area of the enlarged land 62 is the sum of the surface areas of the two standard lands 61 and the surface area of the connection land 64. Therefore, the surface area of the enlarged land 62 is sufficiently greater than twice the surface area of each standard land 61.

The surface area of the enlarged land 62 and the surface area of the standard land 61 refer to the surface area of the enlarged land 62 and the surface area of the standard land 61, respectively, in plan view of the first main surface 51 of the substrate 50 as viewed in the thickness direction.

As shown in FIG. 1, on the substrate 50 of the embodiment, the distance in the first direction X between the outer edges of the primary-side lands 60 located at the opposite ends in the first direction X is referred to as a standard distance K1. As shown in FIG. 5, on the substrate 80 of the reference example, the distance in the first direction X between the outer edges of the standard lands 61 located at the opposite ends in the first direction X is referred to as a reference distance K2. The standard distance K1 is equal to the reference distance K2. Accordingly, the substrate 50 of the embodiment includes the enlarged land 62 without increasing, in the first direction X, the surface area of the region in which the primary-side lands 60 are disposed, as compared to the substrate 80 of the reference example. Furthermore, the substrate 50 of the embodiment does not increase the surface area of the region in which the primary-side lands 60 are disposed in the second direction Y, as compared to the substrate 80 of the reference example.

As shown in FIG. 1, each of the secondary-side lands 70 has a rectangular shape. The secondary-side lands 70 are arranged such that the short sides of all the secondary-side lands 70 extend in the first direction X. The secondary-side lands 70 are arranged in parallel in the first direction X of the substrate 50. Any two of the secondary-side lands 70 that are adjacent to each other in the first direction X of the substrate 50 are separated from each other in the first direction X by a distance greater than or equal to the insulation distance.

Each of the four secondary-side lands 70 is a standard land 71 to which one secondary-side lead terminal 30 is soldered. The primary-side lands 60 and the secondary-side lands 70 are disposed at positions opposite to each other in the second direction Y of the substrate 50. Specifically, at one end in the first direction X of the substrate 50, two standard lands 61 and two standard lands 71 are disposed on the opposite sides from each other in the second direction Y. At the other end in the first direction X of the substrate 50, the enlarged land 62 and two standard lands 71 are disposed on the opposite sides from each other in the second direction Y. No secondary-side land 70 is disposed at a position aligned in the second direction Y with the standard land 61 at the center of the five primary-side lands 60 arranged in parallel in the first direction X.

### Transformer Module

The transformer module 10, which includes the transformer 11 having the above-described configuration and the substrate 50, will now be described.

As shown in FIG. 1, on the primary side of the transformer 11, each of the first lead terminals 21 and the second lead terminals 22 is soldered to the corresponding standard land 61 of the primary-side lands 60 via a solder layer 18. On the primary side of the transformer 11, the joint portions 42 of two of the primary-side lead terminals 20 are soldered to the enlarged land 62 via a solder layer 18. These two primary-side lead terminals 20 are adjacent to each other in the parallel arrangement direction, in which the multiple primary-side lead terminals 20 are arranged in parallel, and have the same electric potential. Therefore, the transformer module 10 includes the enlarged land 62 on the substrate 50. The enlarged land 62 is soldered, via a solder layer 18, to the joint portions 42 of the third lead terminal 23 and the fourth lead terminal 24. The third lead terminal 23 and the fourth lead terminal 24 are adjacent to each other in the parallel arrangement direction, in which the primary-side lead terminals 20 are arranged in parallel, and have the same electric potential. The dummy lead terminal 25 is joined via a solder layer 18 to the standard land 61 located at the center in the parallel arrangement direction of the substrate 50. On the secondary side of the transformer 11, the first lead terminal 31 to the fourth lead terminal 34 are joined to the standard lands 71 of the secondary-side lands 70 via the solder layers 18.

As shown in FIG. 2, the extending portion 41 of each of the primary-side lead terminals 20 soldered to the primary-side lands 60 extends from the lower surface of the primary-side terminal mount 16 toward the substrate 50. Although not illustrated, the extending portion 41 of each of the secondary-side lead terminals 30 soldered to the secondary-side lands 70 extends from the lower surface of the secondary-side terminal mount 17 toward the substrate 50.

As shown in FIG. 3, each of the primary-side lead terminals 20 includes a bent portion 43 that is bent along the substrate 50, and a joint portion 42 that extends along the substrate 50 and is soldered to the corresponding primary-side land 60 via a solder layer 18. Although not illustrated, each of the secondary-side lead terminals 30 includes a bent portion 43 that is bent along the substrate 50, and a joint portion 42 that extends along the substrate 50 and is soldered to the corresponding secondary-side land 70 via a solder layer 18.

As shown in FIGS. 3 and 4, the solder layer 18 is joined to the joint portions 42 over the entire length of the joint portions 42, and is also joined to the distal end faces of the joint portions 42 and the outer surfaces of the bent portions 43. The solder layer 18 is joined to the opposite side surfaces in the transverse direction of each joint portion 42. Thus, the solder layer 18 is joined to the joint portions 42 so as to surround the joint portions 42.

The solder layer 18 that solders the third lead terminal 23 and the fourth lead terminal 24 to the enlarged land 62 includes solder fillet 18a extending downward while being inclined so as to spread from the upper edge of the joint portion 42 toward the outer edge of the standard land 61. That is, the joint portions 42 are joined to the upper portion of the solder layer 18, which is formed so as to rise on the enlarged land 62. The solder fillet 18a extends downward while being inclined so as to spread from the upper ends of the bent portions 43 toward the outer edge of the enlarged land 62. Therefore, the solder layer 18 is joined to the bent portions 43 over the entire height of the bent portions 43. That is, the solder layer 18 covers the entire height of the bent portions 43.

### Operation of the Embodiment

As a specific example of a method of soldering the transformer 11 to the substrate 50, a method of soldering the third lead terminal 23 and the fourth lead terminal 24 to the enlarged land 62 will be described together with operation of the transformer module 10 according to the present embodiment.

First, a solder paste is applied to each of the primary-side lands 60 and the secondary-side lands 70. Next, the joint portions 42 of the primary-side lead terminals 20 are placed on the solder paste applied to the primary-side lands 60, and the joint portions 42 of the secondary-side lead terminals 30 are placed on the solder paste applied to the secondary-side lands 70.

As shown in FIG. 1, since the enlarged land 62 is formed by connecting two standard lands 61 via the connection land 64, the surface area of the enlarged land 62 is sufficiently greater than twice the surface area of each standard land 61. Accordingly, the amount of solder paste that can be applied to the enlarged land 62 is increased. As the amount of the solder paste applied to the enlarged land 62 increases, the solder paste is more likely to flow toward the joint portions 42, and thus the solder paste is more likely to flow toward the bent portions 43. As a result of the solder paste rising along the joint portions 42 and the bent portions 43, the solder layer 18 is joined to the bent portions 43 over the entire height.

### Advantages of the Embodiment

The above-described embodiment has the following advantages.

(1) On the substrate 50, the enlarged land 62 is formed by connecting two standard lands 61 arranged in the parallel arrangement direction via the connection land 64. Therefore, the amount of solder paste that can be applied to the enlarged land 62 is increased as compared with a case in which the solder paste is applied only to one standard land 61. The third lead terminal 23 and the fourth lead terminal 24, which have the same electric potential, are soldered to the enlarged land 62 via a solder layer 18. The solder layer 18 is thus joined to the bent portion 43 of each of the third lead terminal 23 and the fourth lead terminal 24. Consequently, the solder layer 18 reinforces the bent portions 43, in which stress is likely to occur due to vibration or the like.

The enlarged land 62 is formed by connecting, via the connection land 64, two standard lands 61, to which the third lead terminal 23 and the fourth lead terminal 24 of the same electric potential are intended to be soldered. Since the primary-side lands 60 to which the primary-side lead terminals 20 having the same electric potential are soldered do not need to be insulated from each other, the adjacent primary-side lands 60 can be connected to each other via the connection land 64 disposed therebetween. In other words, the enlarged land 62 enlarges the surface area of a land by effectively using the region between the adjacent standard lands 61. Therefore, even though the enlarged land 62 is formed, the arrangement region of the primary-side lands 60 on the substrate 50 is not enlarged in the parallel arrangement direction of the primary-side lands 60. Accordingly, the bent portions 43 are reinforced without increasing the size of the substrate 50.

(2) The solder layer 18 is joined to the third lead terminal 23 and the fourth lead terminal 24, which are soldered to the enlarged land 62, over the entire height of the bent portions 43 via the solder fillet 18a. This reinforces the bent portions 43 in a favorable manner.

(3) The transformer 11 includes the dummy lead terminal 25. The dummy lead terminal 25 is provided in the transformer 11 as a primary-side lead terminal 20. The number of the primary-side lead terminals 20 including the dummy lead terminal 25 is five, and the number of the secondary-side lead terminals 30 is four. Thus, since the primary-side lead terminals 20 and the secondary-side lead terminals 30 can be clearly distinguished from each other, it is possible to prevent the primary-side lead terminals 20 from being soldered to the secondary-side lands 70.

(4) The enlarged land 62 is formed by connecting two standard lands 61 via the connection land 64 over the entire length of the standard lands 61. The enlarged land 62 thus has a rectangular shape. Accordingly, for example, the surface area of the enlarged land 62 is increased as compared with a case in which an H-shaped enlarged land is formed by connecting only parts of the two standard lands 61 in the longitudinal direction via the connection land 64. Consequently, the amount of solder paste that can be applied to the enlarged land 62 is sufficiently increased. In addition, the fluidity of the solder paste applied to the enlarged land 62 is increased as compared with a case in which only parts of the two standard lands 61 in the longitudinal direction are connected via the connection land 64. The solder paste thus readily flows toward the joint portions 42 and the bent portions 43. Accordingly, the bent portions 43 are reinforced by the solder layer 18 formed of the solder paste applied to the enlarged land 62 in a favorable manner.

### Modifications

The above-described embodiment may be modified as follows. The above-described embodiment and the following modifications can be combined as long as the combined modifications remain technically consistent with each other.

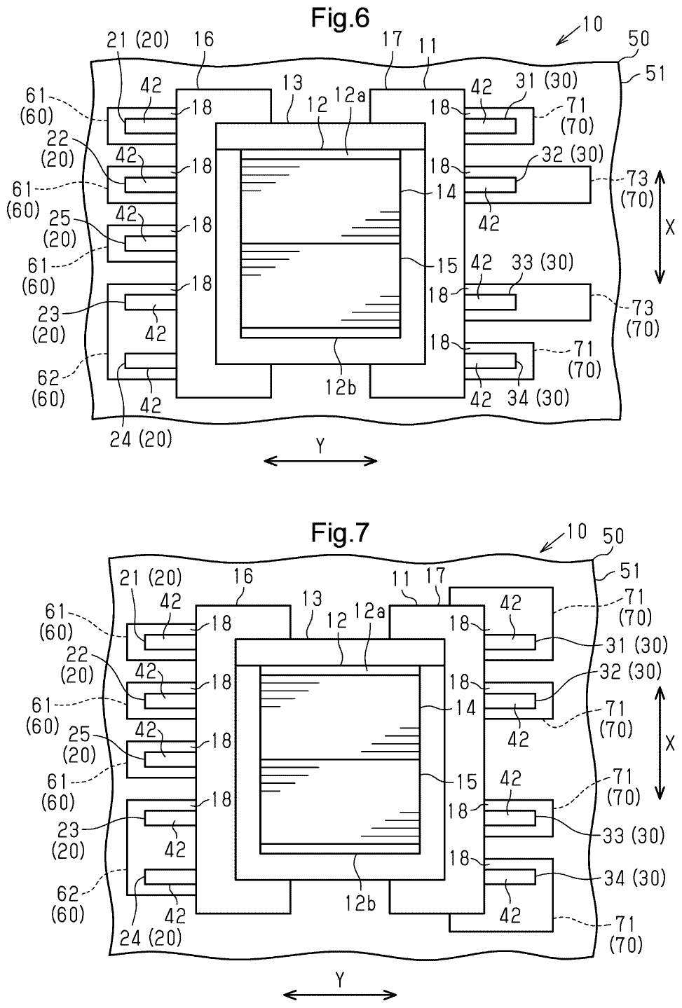

As shown in FIG. 6, as part of the secondary-side lands 70, elongated lands 73 having a longer dimension in the second direction Y than the standard lands 71 may be provided on the substrate 50. Such elongated lands may be provided on the substrate 50 as part of the primary-side lands 60. In such a configuration, the amount of solder paste that can be applied to each elongated land 73 is increased as compared with the amount of solder paste applied to each standard land 71. Accordingly, also in each elongated land 73, the solder layer 18 is joined to the bent portion 43 of the primary-side lead terminal 20 or the secondary-side lead terminal 30. Consequently, the solder layer 18 reinforces the bent portions 43, in which stress is likely to occur due to vibration or the like.

As shown in FIG. 7, among the secondary-side standard lands 71 arranged in parallel in the first direction X, each of the standard lands 71 arranged at the opposite ends in the parallel arrangement direction may be increased in dimension in a direction away from the adjacent standard land 71. Among the standard lands 61 of the primary-side land 60, the standard land 61 disposed at one end in the parallel arrangement direction may also be increased in dimension in a direction away from the adjacent standard land 61.

Accordingly, even a lead terminal other than the third lead terminal 23 and the fourth lead terminal 24, which have the same electric potential, can be soldered to the corresponding standard land 71 with an increased amount of solder paste. Since the dimension of the standard land 71 arranged at least at one end in the parallel arrangement direction is increased in a direction away from the adjacent standard land 71, the standard land 71 arranged at least at one end does not short-circuit with the adjacent standard land 71. Therefore, the bent portion 43 of the secondary-side lead terminal 30 joined to the standard land 71 is readily reinforced.

In the primary-side lands 60, the first lead terminal 21 and the second lead terminal 22, which are arranged in the parallel arrangement direction and have the same electric potential, may be soldered to the enlarged land 62.

In the above-described embodiment, one of the five primary-side lead terminals 20 is used as the dummy lead terminal 25. However, that one lead terminal may be used as a lead terminal that is energized in the same manner as the other four lead terminals of the primary-side lead terminals 20.

In the transformer module 10, the number of the primary-side lead terminals 20 and the number of the secondary-side lead terminals 30 arranged in the parallel arrangement direction may be other than those in the embodiment. The number of the primary-side lead terminals 20 or the secondary-side lead terminals 30 that are adjacent to each other in the parallel arrangement direction and have the same electric potential may be three or more. According to the number of the primary-side lead terminals 20 or the secondary-side lead terminals 30 of the same electric potential, the enlarged land 62 may be formed by connecting the same number of the standard lands 61 as the number of the primary-side lead terminals 20 or the secondary-side lead terminals 30 of the same electric potential via a connection land 64.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A transformer module, comprising:
a transformer including multiple lead terminals electrically connected to corresponding windings, and a terminal mount on which the multiple lead terminals are arranged in parallel; and
a substrate on which multiple lands to which the lead terminals are respectively soldered are arranged in parallel, wherein
each of the lead terminals includes:
a bent portion bent along the substrate; and
a joint portion extending along the substrate,
each joint portion is soldered to the corresponding land via a solder layer,
the lands include an enlarged land and multiple standard lands,
the joint portions of ones of the lead terminals are soldered to the enlarged land via the corresponding solder layer, the ones of the lead terminals being adjacent to each other in a parallel arrangement direction in which the lead terminals are arranged in parallel, and the ones of the lead terminals having a same electric potential,
each joint portion is soldered to one of the standard lands via the corresponding solder layer, and
the enlarged land is formed by connecting, via a connection land and in the parallel arrangement direction, the standard lands to which the lead terminals, adjacent to each other in the parallel arrangement direction and having the same electric potential, are intended to be soldered.

2. The transformer module according to claim 1, wherein
the standard lands are arranged in parallel in the parallel arrangement direction, and
among the standard lands arranged in parallel, the standard land arranged at least at one end in the parallel arrangement direction has a dimension that is increased in a direction away from another standard land adjacent thereto.

3. The transformer module according to claim 1, wherein each solder layer is joined to an entirety of the corresponding bent portion.

4. The transformer module according to claim 1, wherein the connection land connects the standard lands adjacent to each other in the parallel arrangement direction over an entirety of the standard lands in a direction orthogonal to the parallel arrangement direction.
